(19) United States
(12) Patent Application Publication
(10) Pub. No.: US 2021/0282288 A1
(43) Pub. Date: Sep. 9, 2021

(54) APPARATUSES WITH LINEARLY MOVABLE JAWS

(71) Applicant: Hewlett-Packard Development Company, L.P., Spring, TX (US)

(72) Inventor: Clinton Troy Jensen, Boise, ID (US)

(73) Assignee: Hewlett-Packard Development Company, L.P., Spring, TX (US)

(21) Appl. No.: 17/255,487

(22) PCT Filed: Oct. 10, 2018
(86) PCT No.: PCT/US2018/055257

§ 371 Date: Dec. 23, 2020

(51) Int. Cl. H05K 7/12; F16B 5/06

(52) U.S. Cl. CPC H05K 7/12; F16B 5/0621

(57) ABSTRACT

According to examples, an apparatus may include a housing having a bay, the bay having a surface opening. The apparatus may also include a connector attached to the housing and a first jaw movably positioned in the bay, the first jaw having a threaded through hole. The apparatus may further have a threaded fastener extending through the surface opening and threadably engaging the threaded through hole, in which rotation of the threaded fastener is to cause the first jaw to move linearly in the bay to removably lock the connector to a port.

### BACKGROUND

Input/Output (I/O) connectors and ports are common interfaces in numerous devices such as printers, computers, mobile devices, and the like. I/O connectors and ports allow for exchange of information using a standard protocol and may also allow for standardization of connectors. Some I/O ports and connectors may also be used for power transfer.

### BRIEF DESCRIPTION OF DRAWINGS

Features of the present disclosure are illustrated by way of example and not limited in the following figure(s), in which like numerals indicate like elements, in which:

FIG. 1 shows a cross-sectional view of an example apparatus that may be removably locked onto a port;

FIG. 2 shows a perspective view of an example apparatus including the features of the example apparatus depicted in FIG. 1;

FIG. 3 shows a cross-sectional side view of the example apparatus depicted in FIG. 2;

FIGS. 4A and 4B, respectively, show cross-sectional side views of the example apparatus depicted in FIGS. 2 and 3 in respective states of engagement with a port; and

FIGS. 5 and 6, respectively, show cross-sectional side views of example apparatuses to be removably locked onto a port.

### DETAILED DESCRIPTION

For simplicity and illustrative purposes, the principles of the present disclosure are described by referring mainly to examples thereof. In the following description, numerous specific details are set forth in order to provide an understanding of the examples. It will be apparent, however, to one of ordinary skill in the art, that the examples may be practiced without limitation to these specific details. In some instances, well known methods and/or structures have not been described in detail so as not to unnecessarily obscure the description of the examples. Furthermore, the examples may be used together in various combinations.

Throughout the present disclosure, the terms “a” and “an” are intended to denote one of a particular element or multiple ones of the particular element. As used herein, the term “includes” means includes but not limited to, the term “including” means including but not limited to. The term “based on” may mean based in part on.

Many devices, such as computers, printers, mobile devices, and the like, may include an I/O port. Generally, I/O ports, such as the Universal Serial Bus (USB) ports and connectors, High Definition Media Interface (HDMI) ports and connectors, etc., may be used to connect different devices to one another such as printers to computers, computers to monitors, etc. The devices may include a limited number of I/O ports because of size constraints and/or due to costs associated with including the I/O ports on the devices. For example, some mobile devices may include just one I/O port due to the compact dimensions of the mobile device.

Disclosed herein are apparatuses that may include multiple ports and/or connectors that may expand the number of devices that may be connected to each other. In addition, the apparatuses may include mechanisms, e.g., jaws, that may be inserted into and may engage with walls of a port to physically lock the apparatuses with the devices including the ports. The mechanisms may be moved linearly to enable the apparatuses to be removably locked with the ports, e.g., to prevent unintended and/or unauthorized removal of apparatuses from engagement with devices.

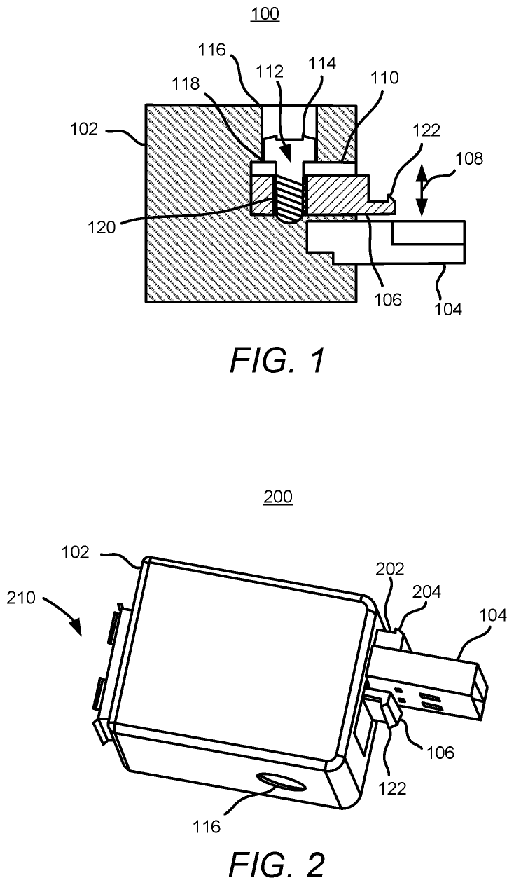

Reference is first made to FIGS. 1 and 2. FIG. 1 shows a cross-sectional side view of an example apparatus 100 that may be removably locked onto a port. FIG. 2 shows a perspective view of an example apparatus 200 including the features of the example apparatus 100 depicted in FIG. 1. It should be understood that the example apparatuses 100, 200 depicted in FIGS. 1 and 2 may include additional components and that some of the components described herein may be removed and/or modified without departing from the scopes of the example apparatuses 100, 200 disclosed herein.

The apparatuses 100, 200 may, for example, be a Universal Serial Bus (USB) splitter, a USB hub, a high-definition multimedia interface (HDMI) splitter, an HDMI cable, a USB connected peripheral device, or the like. In this regard, the apparatuses 100, 200 may each include a housing 102 that may support a connector 104. The housing 102 may be formed of a rigid material, such as a plastic, a metal, a composite material, a ceramic material, or the like. The connector 104 may be a (USB) connector, an HDMI connector, or other type of electrical connector. For instance, the connector 104 may be a male connector. Although not shown, the connector 104 may be connected to other components inside the housing 102 and/or outside of the housing 102 such that electrical signals may be communicated between the connector 102 and the other components.

The apparatuses 100, 200 may also include a first jaw 106 that may removably lock the apparatuses 100, 200 to a port into which the connector 104 may be inserted. That is, the first jaw 106 may be laterally (or equivalently, linearly) movable as denoted by the arrow 108 within a bay 110 of the housing 102 to move from an unlocked position and a locked position as discussed in greater detail herein. The bay 110 may have a surface opening 112 through which a threaded fastener 114 may be inserted into the bay 110. The bay 110 may also be in communication with a slot 116, in which the surface opening 112 may have a smaller diameter or width than the diameter or width of the surface opening 116. As a result, a surface 118 may be formed above the bay 110 around the surface opening 112. As shown in FIG. 1, the threaded fastener 114 may be seated on the surface 118 and may freely rotate with respect to the surface 118.

As also shown, the first jaw 106 may include a through hole 120 through which the threaded fastener 114 may engage the first jaw 106. The through hole 116 may also be threaded such that the threaded fastener 114 may be in threaded engagement with the first jaw 106. In this regard, rotation of the threaded fastener 114 may vary the position of the first jaw 106, e.g., to linearly move the first jaw 106 between an unlocked position and a locked position. In addition, the first jaw 106 may include a first tab 122 to lock the apparatuses 100, 200 to a side wall of a port as discussed in greater detail herein.

According to examples, the threaded fastener 114 may have a security key receptacle at a proximal end of the threaded fastener 114. The security key receptacle may, for instance, prevent rotation of the threaded fastener 114 in one or more both directions without use of a key having a configuration that matches the security key receptacle. As such, for instance, the security key receptacle on the threaded fastener may prevent unwanted or unauthorized locking and/or unlocking of the apparatus 100, 200 to the port of another device.

In some examples, the security key receptacle may be shaped to receive a driver with a shape and a dimension that matches the shape and dimension of the security key receptacle. For example, the security key receptacle may be shaped to receive a driver with a torx shape, a pentagonal shape, or the like.

As shown in FIG. 2, the apparatus 200 may also include a second jaw 202 that may disposed opposite to the first jaw 106. For instance, the second jaw 202 may be disposed with respect to the first jaw 106 such that the connector 104 is positioned between the first jaw 106 and the second jaw 202. In other examples, however, the connector 104 may be positioned on either side of the first jaw 106 or the second jaw 202. In any of these examples, the second jaw 202 may be fixed to the housing 102 or the second jaw 202 may be movable in similar respects to the movement of the first jaw 106. In addition, the second jaw 202 may include a second tab 204 to also lock (or similarly, attach, engage, etc.) the apparatus 200 to a side wall of a port as discussed in greater detail herein. The second tab 204 of the second jaw 202 may extend in a second direction and the first tab 122 of the first jaw 106 may extend in a first direction. In examples, the second direction may be opposite to the first direction, while in other examples, the second tab 204 may face the same direction as the first tab 122.

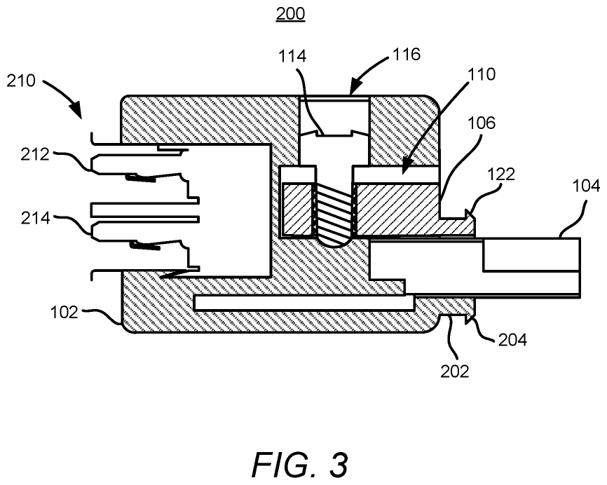

Reference is now made to FIGS. 2 and 3. FIG. 3 shows a cross-sectional side view of the example apparatus 200 depicted in FIG. 2. As shown in FIGS. 2 and 3, the apparatus 200 may also include an output connector 210 into which a mating connector (not shown) may be inserted. As shown, the output connector 210 may include a plurality of female connectors 212, 214 in which mating male connectors may be inserted. In some examples, therefore, the apparatus 200 may be a splitter that may split input and/or output from the connector 104 to the output connector 210 or vice versa. Although the output connector 210 is depicted as having two female connectors, it should be understood that the output connector 210 may include any suitable number of female connectors and/or may instead include any suitable number of male connectors.

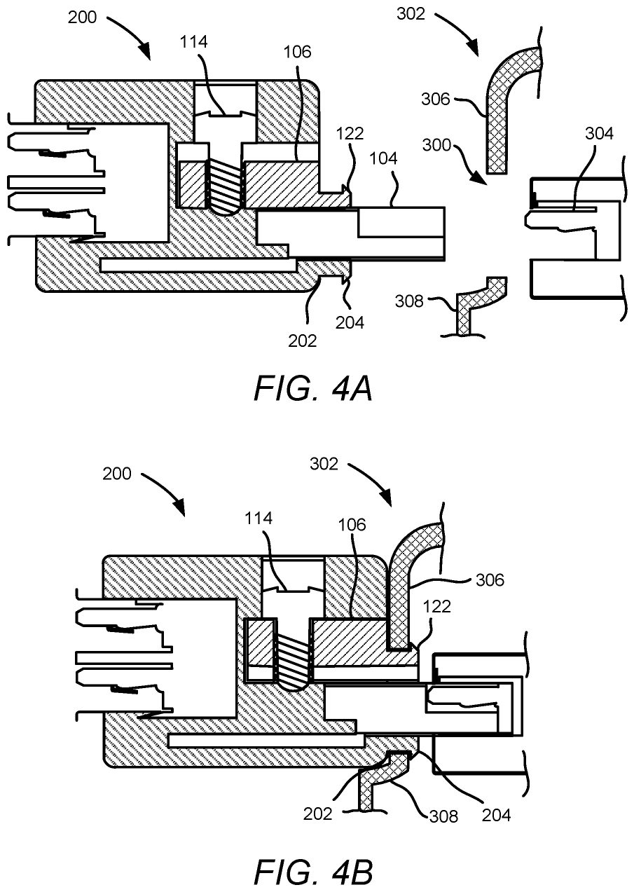

Turning now to FIGS. 4A and 4B, there are respectively shown cross-sectional side views of the example apparatus 200 depicted in FIGS. 2 and 3 in respective states of engagement with a port 300. That is, FIG. 4A depicts the apparatus 200 prior to insertion into the port 300 and FIG. 4B depicts the apparatus 200 following insertion into the port 300 and following movement of the first jaw 106 into a locking position.

As shown, the port 300 may be formed as part of an external portion of a device 302. The device 302 may be, for instance, a laptop computer, a desktop computer, a printer, a multifunction printing device, or the like. In addition, an I/O connector 304 that may mate with the connector 104 of the apparatus 200 may be provided in the port 300. In some examples, the connector 104 of the apparatus 200 may be inserted into the I/O connector 304 to enable electrical signals and/or power to be conveyed through the connection.

As also shown FIG. 4A, the external portion of the device 302 around the port 300 may include a first side wall 306 and a second side wall 308. Additional side walls may be provided on the remaining two sides of the port 300. The first jaw 106 may be in a first position, e.g., close to the connector 104, prior to insertion into the port 300. As a result, the first tab 122, along with the connector 104 and the second tab 204, may be inserted into the port 300, which may cause the connector 104 to be inserted into the I/O port 304.

Following insertion of the first tab 122 into the port 300, the threaded fastener 114 may be rotated in a first direction, e.g., a clockwise direction, which may cause the first jaw 106 to move linearly with respect to the second jaw 202. For instance, rotation of the threaded fastener 114 in the first direction may cause the first jaw 106 to move linearly away from the second jaw 202, thus increasing the distance between the first jaw 106 and the second jaw 202. Similarly, rotation of the threaded fastener 114 in a second direction, e.g., a counterclockwise direction, opposite to the first direction may cause the first jaw 106 to move linearly towards the second jaw 202, thus decreasing the distance between the first jaw 106 and the second jaw 202.

As shown in FIG. 4B, following rotation of the threaded fastener 114 in the first direction, the first jaw 106 may move linearly toward the first side wall 306 such that a portion of the first jaw 106 may be in contact with the first side wall 306. The first tab 122 may engage with the first side wall 306 when the first jaw 106 is moved sufficiently in the direction of the first side wall 306. In addition, the second jaw 202 may be in contact with the second side wall 308 such that the second tab 204 may engage with the second side wall 308. The engagement between the first tab 122 and the first side wall 306 and the second tab 204 and the second side wall 308 may prevent removal of the apparatus 200 from the port 300 and thus, may lock the apparatus 200 onto the device 302.

To remove the apparatus 200 from the device 302, the threaded fastener 114 may be rotated in the second direction, which may cause the first jaw 106 to be moved linearly away from the first side wall 306. Once the first jaw 106 has been moved a sufficient distance to enable the first tab 122 to clear the port 300 opening, the apparatus 200 may be removed from the device 302 to disengage the connector 104 from the I/O port 304.

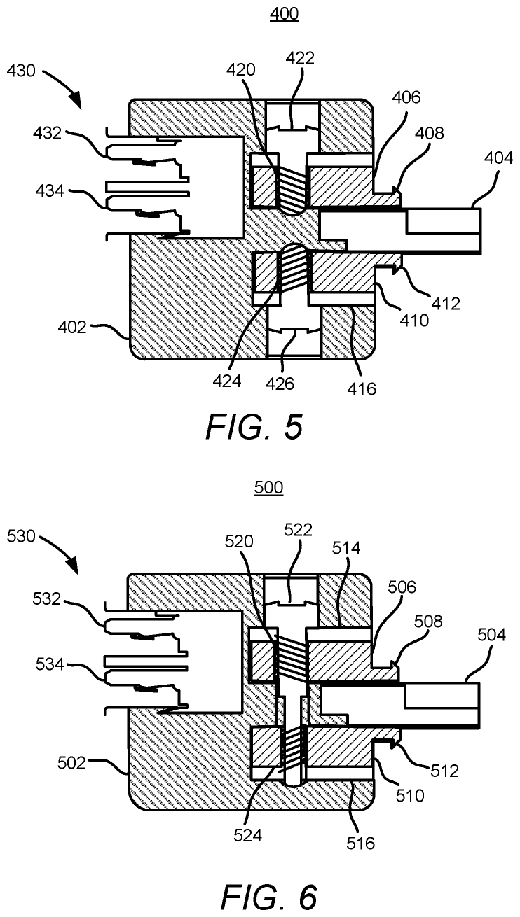

Reference is now made to the FIGS. 5 and 6, which respectively show cross-sectional side views of example apparatuses 400 and 500 to be removably locked onto a port. It should be understood that the example apparatuses 400, 500 depicted in FIGS. 5 and 6 may include additional components and that some of the components described herein may be removed and/or modified without departing from the scopes of the example apparatuses 400, 500 disclosed herein.

The apparatuses 400 and 500 may each be similar to the apparatuses 100, 200 discussed above and thus, may be a USB splitter, a USB hub, an HDMI splitter, an HDMI cable a USB connected peripheral device, or the like. In this regard, the apparatuses 400, 500 may each include a housing 402, 502 that may support a connector 404, 504. Each of the housings 402, 502 may be formed of a rigid material, such as plastic, a metal, a composite material, a ceramic material, or the like. Each of the connectors 404, 504 may be a (USB) connector, an HDMI connector, or other type of electrical connector. For instance, each of the connectors 404, 504 may be a male connector. Although not shown, the connectors 404, 504 may be connected to other components inside the housing 402, 502 and/or outside of the housing 402, 502.

As shown in FIG. 5, the apparatus 400 may include a first jaw 406 having a first tab 408 and a second jaw 410 having a second tab 412. The apparatus 400 may also include in a first bay 414 within which the first jaw 406 may be linearly movable and a second bay 416 within which the second jaw 410 may be linearly movable. The first jaw 406 may include a first threaded through hole 420 into which a first threaded fastener 422 may be threadably engaged and the second jaw 410 may include a second threaded through hole 424 into which a second threaded fastener 426 may be threadably engaged. As such, rotation of the first threaded fastener 422 may cause the first jaw 406 to be moved linearly within the first bay 414. Likewise, rotation of the second threaded fastener 426 may cause the second jaw 410 to be moved linearly within the second bay 416.

The first jaw 406 and the second jaw 410 may thus be separately movable with respect to each other, for instance, to individually engage a first side wall 306 and a second side wall 308. A manner in which the first jaw 406 and the second jaw 410 may respectively engage the first side wall 306 and the second side wall 308 to lock the apparatus 400 to a port 300 of a device 302 is discussed above with respect to FIGS. 4A and 4B.

The apparatus 400 may also include an output connector 430 into which a mating connector (not shown) may be inserted. As shown, the output connector 430 may include a plurality of female connectors 432, 434 in which mating male connectors may be inserted. In some examples, therefore, the apparatus 400 may be a splitter that may split input and/or output from the connector 404 to the output connector 430 or vice versa. Although the output connector 430 is depicted as having two female connectors, it should be understood that the output connector 430 may include any suitable number of female connectors and/or may instead include any suitable number of male connectors.

As shown in FIG. 6, the apparatus 500 may include a first jaw 506 having a first tab 508 and a second jaw 510 having a second tab 512. The apparatus 500 may also include a first bay 514 within which the first jaw 506 may be linearly movable and a second bay 516 within which the second jaw 510 may be linearly movable. The first jaw 506 may include a first threaded through hole 520 into which a threaded fastener 522 may be threadably engaged and the second jaw 510 may include a second threaded through hole 524 through which the threaded fastener 522 may be threadably engaged. The second threaded through hole 524 may have a smaller diameter than the first threaded through hole 520 and the threaded fastener 522 may have a smaller diameter at a lower section of the threaded fastener 522 such that the lower section of the threaded fastener 522 may pass through the first threaded through hole 520.

The threads in the second thread hole 524 may be angled in an opposite thread direction from the threads in the first thread hole 522. The threads in the threaded fastener 522 may be similarly angled. As such, rotation of the threaded fastener 522 in a first direction may cause the first jaw 506 to move in a first direction and may cause the second jaw 510 to move in a second direction opposite the first direction, e.g., away from other. Likewise, rotation of the threaded fastener 522 in a second direction may cause the first jaw 506 to move in the second direction and may cause the second jaw 510 to move in the first direction opposite the second direction, e.g., toward each other.

The first jaw 506 and the second jaw 510 may thus be separately movable with respect to each other, for instance, to individually engage a first side wall 306 and a second side wall 308. A manner in which the first jaw 506 and the second jaw 510 may respectively engage the first side wall 306 and the second side wall 308 to lock the apparatus 500 to a port 300 of a device 302 is discussed above with respect to FIGS. 4A and 4B.

The apparatus 500 may also include an output connector 530 into which a mating connector (not shown) may be inserted. As shown, the output connector 530 may include a plurality of female connectors 532, 534 in which mating male connectors may be inserted. In some examples, therefore, the apparatus 500 may be a splitter that may split input and/or output from the connector 504 to the output connector 530 or vice versa. Although the output connector 530 is depicted as having two female connectors, it should be understood that the output connector 530 may include any suitable number of female connectors and/or may instead include any suitable number of male connectors.

Although described specifically throughout the entirety of the instant disclosure, representative examples of the present disclosure have utility over a wide range of applications, and the above discussion is not intended and should not be construed to be limiting but is offered as an illustrative discussion of aspects of the disclosure.

What has been described and illustrated herein is an example of the disclosure along with some of its variations. The terms, descriptions and figures used herein are set forth by way of illustration only and are not meant as limitations. Many variations are possible within the spirit and scope of the disclosure, which is intended to be defined by the following claims—and their equivalents—in which all terms are meant in their broadest reasonable sense unless otherwise indicated.

What is claimed is:

1. An apparatus comprising:
a housing having a bay, the bay having a surface opening;
a connector attached to the housing;
a first jaw movably positioned in the bay, the first jaw having a threaded through hole; and
a threaded fastener extending through the surface opening and threadably engaging the threaded through hole, wherein rotation of the threaded fastener is to cause the first jaw to move linearly in the bay to removably lock the connector to a port.

2. The apparatus of claim 1, further comprising:
a second jaw disposed opposite to the first jaw.

3. The apparatus of claim 2, wherein the first jaw has a first tab and the second jaw has a second tab, wherein the first tab extends in a first direction and the second tab extends in a second direction, the second direction being opposite to the first direction.

4. The apparatus of claim 2, wherein the connector is attached to the housing between the first jaw and the second jaw.

5. The apparatus of claim 2, wherein the second jaw is fixed to the housing.

6. The apparatus of claim 2, wherein the second jaw is movable with respect to the first jaw.

7. The apparatus of claim 1, wherein the threaded fastener has a security key receptacle at a proximal end of the threaded fastener.

8. The apparatus of claim 1, further comprising:
an output connector attached to the housing.

9. An apparatus comprising:
a housing;
a first jaw and a second jaw disposed opposite to each other in the housing, the first jaw having a first threaded through hole and the second jaw having a second threaded through hole;
a first threaded fastener engaged with the first jaw through the first threaded through hole, wherein rotation of the first threaded fastener transposes the first jaw with respect to the second jaw; and
a second threaded fastener engaged with the second jaw through the second threaded through hole, wherein rotation of the second threaded fastener transposes the second jaw with respect to the first jaw.

10. The apparatus of claim 9, wherein rotation of the first threaded fastener transposes the first jaw linearly with respect to the second jaw.

11. The apparatus of claim 9, wherein the first threaded fastener has a first security key receptacle and the second threaded fastener has a second security key receptacle.

12. The apparatus of claim 9, further comprising a connector attached to the housing between the first jaw and the second jaw, wherein the first jaw has a first tab and the second jaw has a second tab, the second tab extending in a direction opposite the first tab.

13. The apparatus of claim 9, further comprising:
an input/output splitter attached to the housing.

14. An apparatus comprising:
a housing having a bay;
a first jaw disposed in the bay, the first jaw having a first threaded through hole;
a second jaw having a second threaded through hole, the threads in the second threaded through hole being directed in an opposite thread direction from the first threaded through hole; and
a threaded fastener threadably engaging the first threaded through hole and the second threaded through hole, wherein rotation of the threaded fastener in a first direction is to cause the first jaw and the second jaw to move away from each other and rotation of the threaded fastener in a second direction is to cause the first jaw and the second jaw to move toward each other.

15. The apparatus of claim 14, further comprising a connector attached to the housing between the first jaw and the second jaw, wherein the first jaw has a first tab and the second jaw has a second tab, the second tab extending in a direction opposite the first tab.
